(19) United States
(12) Patent Application Publication
(10) Pub. No.: US 2026/0352193 A1
(43) Pub. Date: Nov. 5, 2026

(54) GLITCH FILTER AND ASSOCIATED FLASH MEMORY CONTROLLER

(71) Applicant: Silicon Motion, Inc., Hsinchu County (TW)

(72) Inventor: Chen-Liang Ma, Taoyuan City (TW)

(73) Assignee: Silicon Motion, Inc., Hsinchu County (TW)

(21) Appl. No.: 19/199,374

(22) Filed: May 5, 2025

(51) Int. Cl. H03K 5/133; H03K 5/08; H03K 19/21; H03L 7/093

(52) U.S. Cl. CPC H03K 5/133; H03K 5/088; H03K 19/215; H03L 7/093

(57) ABSTRACT

The present invention provides a glitch filter including a delay chain, a first control circuit, a second control circuit, a first transistor, a second transistor, a first switch and the second switch. The delay chain is configured to delay an input signal to generate a delayed input signal. The first control circuit is configured to receive the input signal and the delayed input signal to generate a first control signal. The second control circuit is configured to receive the input signal and the delayed input signal to generate a second control signal. The first transistor and the second transistor receive the input signal to generate an output signal. The first switch is configured to selectively couple a supply voltage to the first transistor according to the first control signal. The second switch is configured to selectively couple a ground voltage to the second transistor according to the second control signal.

### BACKGROUND OF THE INVENTION

### 1. Field of the Invention

The present invention relates to a glitch filter.

### 2. Description of the Prior Art

In the realm of signal processing, the integrity of the received signal is important for accurate analysis and reliable system operation. However, real-world signals are often susceptible to transient disturbances known as ‘glitches’, which are short-duration, unexpected pulses or noise spikes. The presence of these glitches in the received signal of a receiver can significantly impede subsequent signal processing stages and lead to various detrimental effects.

In order to improve the quality of received signals, a glitch filter was developed to filter out glitches in the received signals. Traditionally, glitch filters have been implemented using RC filters and Schmitt triggers. However, this design will cause significant distortion and mismatch in the signal, which affects subsequent signal processing.

### SUMMARY OF THE INVENTION

Therefore, one of the objectives of the present invention is to provide a glitch filter that can effectively filter out glitches without causing distortion and mismatch to the received signal, thereby solving the problems described in the prior art.

According to one embodiment of the present invention, a glitch filter comprising a delay chain, a first control circuit, a second control circuit, a first transistor, a second transistor, a first switch and the second switch is disclosed. The delay chain is configured to delay an input signal to generate a delayed input signal. The first control circuit is configured to receive the input signal and the delayed input signal to generate a first control signal. The second control circuit is configured to receive the input signal and the delayed input signal to generate a second control signal. The first transistor and the second transistor are configured to receive the input signal to generate an output signal. The first switch is coupled between the first transistor and a supply voltage, and is configured to selectively couple the supply voltage to the first transistor according to the first control signal. The second switch is coupled between the second transistor and a ground voltage, and is configured to selectively couple the ground voltage to the second transistor according to the second control signal.

According to one embodiment of the present invention, a flash memory controller is disclosed. The flash memory controller is used to access a flash memory module, and the flash memory controller comprises a read-only memory configured to store a program code, a microprocessor configured to execute the program code to control access of the flash memory module, an interface logic coupled to a host device, and a control logic coupled to the flash memory module. The control logic or an interface logic comprises a glitch filter. The glitch filter comprises a delay chain, a first control circuit, a second control circuit, a first transistor, a second transistor, a first switch and the second switch. The delay chain is configured to delay an input signal to generate a delayed input signal. The first control circuit is configured to receive the input signal and the delayed input signal to generate a first control signal. The second control circuit is configured to receive the input signal and the delayed input signal to generate a second control signal. The first transistor and the second transistor are configured to receive the input signal to generate an output signal. The first switch is coupled between the first transistor and a supply voltage, and is configured to selectively couple the supply voltage to the first transistor according to the first control signal. The second switch is coupled between the second transistor and a ground voltage, and is configured to selectively couple the ground voltage to the second transistor according to the second control signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a memory device according to an embodiment of the present invention.

FIG. 2 is a diagram illustrating a glitch filter according to one embodiment of the present invention

FIG. 3 is a timing diagram of some signals within the glitch filter according to one embodiment of the present invention.

FIG. 4 is a diagram illustrating a configurable delay chain according to one embodiment of the present invention.

### DETAILED DESCRIPTION

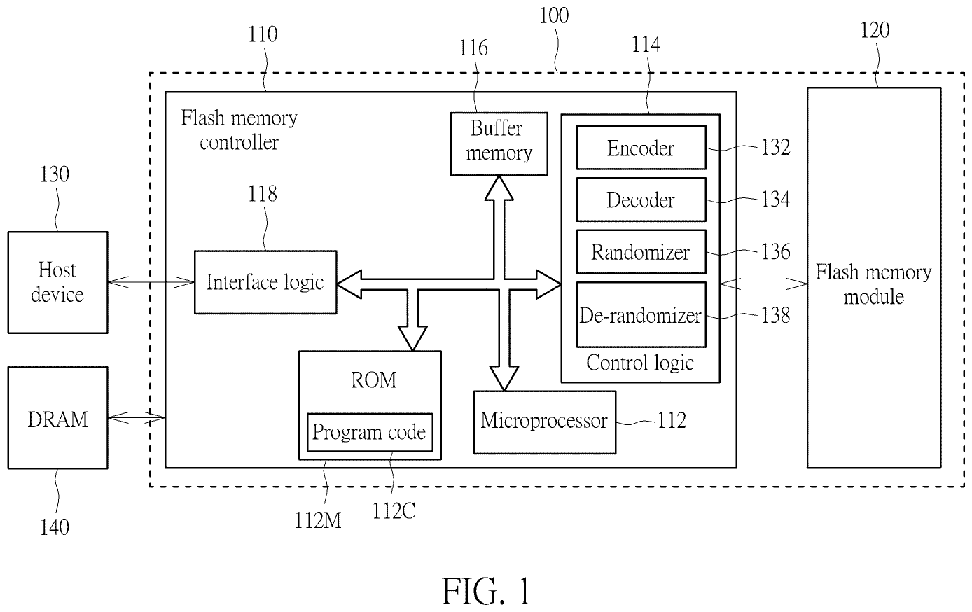

FIG. 1 is a diagram illustrating a memory device 100 according to an embodiment of the present invention. The memory device 100 includes a flash memory module 120 and a flash memory controller 110, wherein the flash memory controller 110 is arranged to access the flash memory module 120. The flash memory controller 110 includes a microprocessor 112, a read only memory (ROM) 112M, a control logic 114, a buffer memory 116 and an interface logic 118. The ROM 112M is arranged to store a program code 112C, and the microprocessor 112 is arranged to execute the program code 112C to control access of the flash memory module 120. The control logic 114 includes an encoder 132, a decoder 134, a randomizer 136 and a de-randomizer 138. The encoder 132 is arranged to encode data that is written into the flash memory module 120 to generate a corresponding parity (also known as an error correction code (ECC)), and the decoder 134 is arranged to decode data that is read from the flash memory module 120. The randomizer 136 is used to randomize the data written to the flash memory module 120, and the de-randomizer 138 is used to de-randomize the data read from the flash memory module 120.

In a general situation, the flash memory module 120 includes a plurality of flash memory chips, and each flash memory chip includes a plurality of blocks. A controller (e.g. the flash memory controller 110 that executes the program code 112C through the microprocessor 112) may copy, erase, and merge data for the flash memory module 120 with a block as a unit. In addition, a block can record a specific number of pages, wherein the controller (e.g. the flash memory controller 110 that executes the program code 112C through the microprocessor 112) may perform a data write operation upon the flash memory module 120 with a page as a unit. In other words, a block is the smallest erase unit in the flash memory module 120, and a page is the smallest write unit in the flash memory module 120.

In practice, the flash memory controller 110 that executes the program code 112C through the microprocessor 112 may utilize its own internal components to perform many control operations. For example, the flash memory controller 122 utilizes the control logic 114 to control access of the flash memory module 120 (more particularly, access at least one block or at least one page), utilizes the buffer memory 116 and/or a DRAM 140 to perform a required buffering operation, and utilizes the interface logic 118 to communicate with a host device 130.

In one embodiment, the memory device 100 may be a portable memory device such as a memory card which conforms to one of the SD/MMC, CF, MS and XD specifications, and the host device 130 is an electronic device able to be connected to the memory device 100, such as a cellphone, a laptop, a desktop computer, etc. In another embodiment, the memory device 100 can be a solid state drive (SSD) or an embedded storage device conforming to the universal flash storage (UFS) or embedded multi-media card (EMMC) specifications, and can be arranged in an electronic device. For example, the memory device 100 can be arranged in a cellphone, a watch, a portable medical testing device (e.g. a medical wristband), a laptop, or a desktop computer. In this case, the host device 130 can be a processor of the electronic device.

In this embodiment, the flash memory module 120 is a three-dimensional (3D) NAND-type flash memory, in which each block is composed of multiple word lines, multiple bit lines and multiple memory cells. Since the 3D NAND flash memory architecture is well known to those with ordinary knowledge in the art, no further explanation is given in the specification.

In the flash memory controller 110, the interface logic 118 comprises a plurality of receiving circuits configured to receive signals, such as command signals or control signals, from the host device 118, and the control logic 114 also comprises a plurality of receiving circuits configured receive signals from the flash memory module 120. As illustrated in the background of the invention, the received signals may have glitches that may affect the subsequent signal processing. Therefore, the interface logic 118 and/or the control logic 114 comprise glitch filters used to filter out the glitches in the received signals.

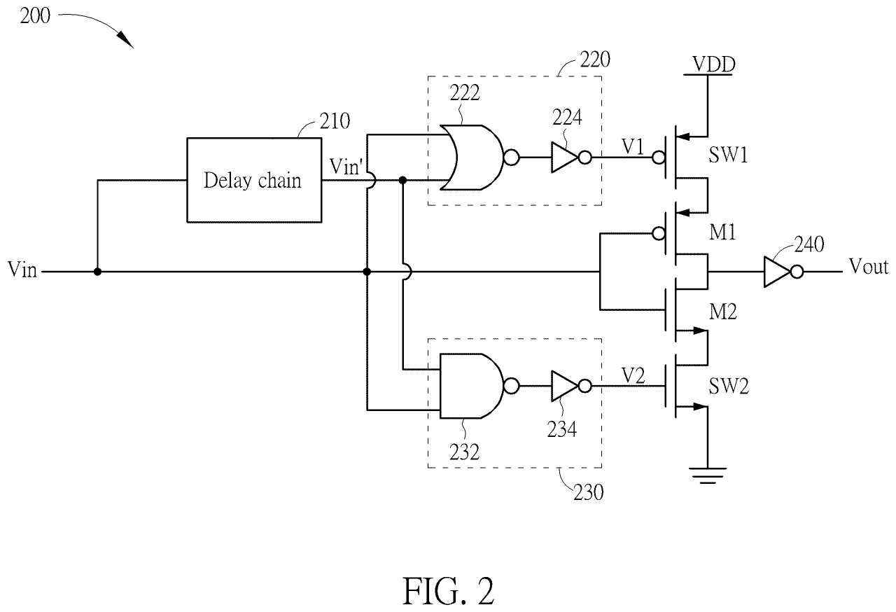

FIG. 2 is a diagram illustrating a glitch filter 200 according to one embodiment of the present invention, wherein the glitch filter 200 is configured to receive and input signal Vin, and to filter out glitches within the input signal Vin to generate an output signal Vout. As shown in FIG. 2, the glitch filter 200 comprises a delay chain 210, a first control circuit 220, a second control circuit 230, two transistors M1 and M2, two switches SW1 and SW2, and an inverter 240. The transistor M1 is implemented by a P-type transistor such as P-type Metal Oxide Semiconductor Field Effect Transistors (MOSFETs), wherein a source electrode of the transistor M1 is coupled to a supply voltage VDD via a switch SW1, a gate electrode of the transistor M1 is used to receive the input signal Vin, and a drain electrode of the transistor is coupled to a ground voltage via the transistor M2 and the switch SW2. The transistor M2 is implemented by an N-type transistor such as N-type MOSFET, wherein a source electrode of the transistor M2 is coupled to the drain electrode of the transistor M1, a gate electrode of the transistor M2 is used to receive the input signal Vin, and a drain electrode of the transistor M2 is coupled to the ground voltage via the switch SW2. The switch SW1 is implemented by a P-type transistor such as a P-type MOSFET, wherein the switch SW1 is controlled by a first control signal V1 to connect the supply voltage VDD to the transistor M1 or disconnect the transistor M1 from the supply voltage VDD. The switch SW2 is implemented by an N-type transistor such as a N-type MOSFET, wherein the switch SW2 is controlled by a second control signal V2 to connect the transistor M1 to the ground voltage or disconnect the transistor M2 from the ground voltage. The delay chain 210 can be implemented by using multiple buffer circuits, and the delay chain 210 is configured to delay the input signal Vin to generate a delayed input signal Vin′. The first control circuit 220 comprises a NOR gate 222 and an inverter 224, and the first control circuit 220 is configured to receive the input signal Vin and the delayed input signal Vin′ to generate the first control signal V1. The second control circuit 230 comprises a NAND gate 232 and an inverter 234, and the second control circuit 230 is configured to receive the input signal Vin and the delayed input signal Vin′ to generate the second control signal V1.

In this embodiment, the amount of delay introduced to the input signal Vin by the delay chain 210 represents the glitch width that the glitch filter 200 can filter out. For example, if the delay chain 210 is designed to have 1-microsecond delay, then the glitch filter 200 can filter out glitches with a width smaller than 1-microsecond. If the delay chain 210 is designed to have 50-nanosecond delay, then the glitch filter 200 can filter out glitches with a width smaller than 50-nanosecond.

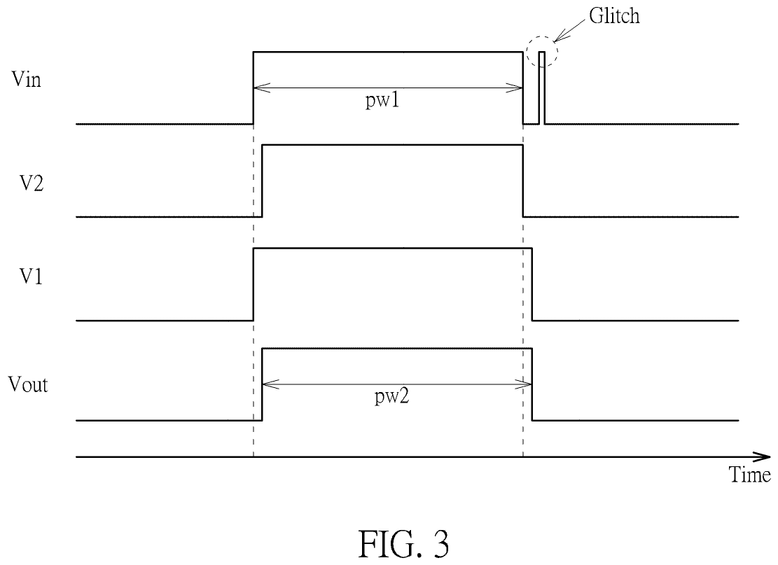

In the operation of the glitch filter 200, referring to FIG. 3 together, the glitch filter 200 receives the input signal Vin with a pulse (normal pulse) and a glitch. The delay chain 210 delays the input signal Vin to generate the delayed input signal Vin′. The first control circuit 220 receives the input signal Vin and the delayed input signal Vin′ to generate the first control signal V1 to the switch SW1, wherein the first control signal V1 enables the switch SW1 when any one of the input signal Vin and the delayed input signal Vin′ have an enabling state (i.e., high voltage level, logical value “1”), and the first control signal V1 disables the switch SW1 when both the input signal Vin and the delayed input signal Vin′ do not have the enabling state (i.e., both the input signal Vin and the delayed input signal Vin′ have low voltage levels, logical value “0”). Simultaneously, the second control circuit 230 receives the input signal Vin and the delayed input signal Vin′ to generate the second control signal V1 to the switch SW2, wherein the second control signal V2 enables the switch SW2 when both the input signal Vin and the delayed input signal Vin′ have the enabling state, and the second control signal V2 disables the switch SW2 when any one of the input signal Vin and the delayed input signal Vin′ does not have the enabling state. Then, the transistors M1 and M2 receive the input signal Vin to generate the output signal Vout via the inverter 240, based on the states of the switches SW1 and SW2.

In the embodiments shown in FIG. 2 and FIG. 3, when the input

signal Vin has a normal pulse whose pulse width ‘pw1’ is greater than the defined glitch width (i.e., delay amount provided by the delay chain 210), this normal pulse can pass through the glitch filter 200 without distortion and mismatch (i.e., the pulse width ‘pw1’ of the input signal Vin is substantially the same as the pulse width ‘pw2’ of the output signal Vout).

In addition, when the input signal Vin has a glitch whose glitch width is less than the delay amount provided by the delay chain 210, as shown in FIG. 3, this glitch will not appear in the output signal Vout, because the second control signal V2 will disable the switch SW2 when any one of the input signal Vin and the delayed input signal Vin′ does not have the enabling state. Specifically, when the input signal Vin has a glitch whose glitch width is less than the delay amount provided by the delay chain 210, the second control signal V2 will always have a low voltage level to disable the switch SW2, so that an output node of the inverter comprising transistors M1 and M2 has high voltage level and will not be discharged. Therefore, the output signal Vout maintains a low voltage level without being influenced by the glitch in the input signal Vin.

It is noted that the components with the first logical circuit 220 and the second logical circuit 230 are for illustrative, not a limitation of the present invention. In other words, as long as the first control circuit 220 generates the first control signal V1 to enable the switch SW1 when any one of the input signal Vin and the delayed input signal Vin′ have the enabling state, and the second control circuit 230 generates the second control signal V2 to enable the switch SW2 only when both the input signal Vin and the delayed input signal Vin′ have the enabling state, the first logical circuit 220 and the second logical circuit 230 can be implemented by using any suitable logical component(s).

In one embodiment of the present invention, the delay chain 210 can be implemented by a configurable delay chain, that is the delay amount provided by the delay chain 210 is adjustable.

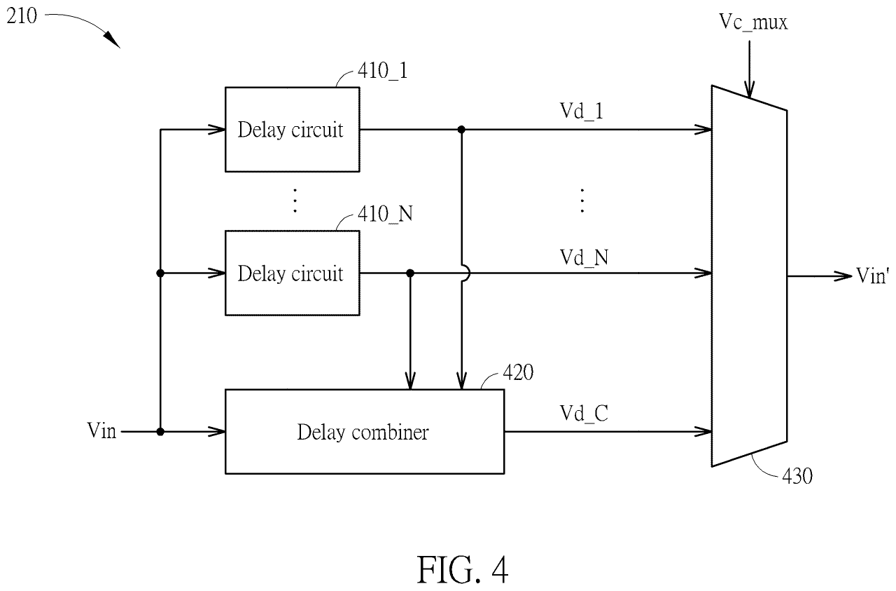

FIG. 4 is a diagram illustrating the delay chain 210 according to one embodiment of the present invention. As shown in FIG. 4, the delay chain comprises a plurality of delay circuits 410_1-410_N, a delay combiner 420 and a multiplexer 430, wherein the plurality of delay circuits 410_1-410_N provide different delay amount. The delay combiner 420 is configured to add the delay amount of part of delay circuits 410_1-410_N. For example, assuming that the delay circuit 410_1 provides a delay of 0.5 microseconds, and the delay circuit 410_N provides a delay of 1-microseconds, the delay combiner 420 can combine the delay amount provided by the delay circuits 410_1 and 410_N to have the delay of 1.5 microseconds. In the operation of the delay chain 210 shown in FIG. 4, the delay circuits 410_1-410_N and the delay combiner 420 delay the input signal Vin to generate delayed signals Vd_1-Vd_N and Vd_C, respectively. Then, the multiplexer 430 selects one of the delayed signals Vd_1-Vd_N and Vd_C, based on a multiplexer control signal Vc_mux, to serve as the delayed input signal Vin′.

Briefly summarized, in the glitch filter of the present invention, by designing the glitch filter with the delay chain, the first control circuit, the second control circuit and the switches shown in FIG. 1, the glitch filter that can effectively filter out glitches without causing distortion and mismatch to the input signal, thereby solving the problems described in the prior art.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A glitch filter, comprising:
a delay chain, configured to delay an input signal to generate a delayed input signal;
a first control circuit, configured to receive the input signal and the delayed input signal to generate a first control signal;
a second control circuit, configured to receive the input signal and the delayed input signal to generate a second control signal;
a first transistor and a second transistor, configured to receive the input signal to generate an output signal;
a first switch, coupled between the first transistor and a supply voltage, configured to selectively couple the supply voltage to the first transistor according to the first control signal; and
a second switch, coupled between the second transistor and a ground voltage, configured to selectively couple the ground voltage to the second transistor according to the second control signal.

2. The glitch filter of claim 1, wherein the first control circuit is configured to generate the first control signal to enable the first switch when any one of the input signal and the delayed input signal has an enabling state, and to disable the first switch when both the input signal and the delayed input signal do not have the enabling state; and the second control circuit is configured to generate the second control signal to enable the second switch when both the input signal and the delayed input signal have the enabling state, and to disable the second switch when any one of the input signal and the delayed input signal does not have the enabling state.

3. The glitch filter of claim 1, wherein the first transistor is a P-type transistor, the second transistor is an N-type transistor, the first switch is the P-type transistor, and the second switch is the N-type transistor.

4. The glitch filter of claim 3, wherein the first control circuit comprises an XOR gate and an inverter.

5. The glitch filter of claim 3, wherein the second switch comprises an NAND gate and an inverter.

6. The glitch filter of claim 1, wherein the delay chain is a configurable delay chain.

7. The glitch filter of claim 1, wherein the delay chain comprises:
a plurality of delay circuits with different delay amount, configured to delay the input signal to generate a plurality of delayed signals, respectively; and
a multiplexer, configured to select one of the plurality of delayed signals to serve as the delayed input signal.

8. The glitch filter of claim 1, wherein the glitch filter is configured to filter out a glitch whose glitch width is smaller than delay amount provided by the delay chain.

9. A flash memory controller, wherein the flash memory controller is used to access a flash memory module, and the flash memory controller comprises:
a read-only memory, configured to store a program code;
a microprocessor, configured to execute the program code to control access of the flash memory module;
an interface logic, coupled to a host device; and
a control logic, coupled to the flash memory module;
wherein the interface logic or the control logic comprises a glitch filter, and the glitch filter comprises:
a delay chain, configured to delay an input signal to generate a delayed input signal;
a first control circuit, configured to receive the input signal and the delayed input signal to generate a first control signal;
a second control circuit, configured to receive the input signal and the delayed input signal to generate a second control signal;
a first transistor and a second transistor, configured to receive the input signal to generate an output signal;
a first switch, coupled between the first transistor and a supply voltage, configured to selectively couple the supply voltage to the first transistor according to the first control signal; and
a second switch, coupled between the second transistor and a ground voltage, configured to selectively couple the ground voltage to the second transistor according to the second control signal.

10. The flash memory controller of claim 9, wherein the first control circuit is configured to generate the first control signal to enable the first switch when any one of the input signal and the delayed input signal has an enabling state, and to disable the first switch when both the input signal and the delayed input signal do not have the enabling state; and the second control circuit is configured to generate the second control signal to enable the second switch when both the input signal and the delayed input signal have the enabling state, and to disable the second switch when any one of the input signal and the delayed input signal does not have the enabling state.

11. The flash memory controller of claim 9, wherein the first transistor is a P-type transistor, the second transistor is an N-type transistor, the first switch is the P-type transistor, and the second switch is the N-type transistor.

12. The flash memory controller of claim 11, wherein the first control circuit comprises an XOR gate and an inverter.

13. The flash memory controller of claim 11, wherein the second switch comprises an NAND gate and an inverter.

14. The flash memory controller of claim 9, wherein the delay chain is a configurable delay chain.

15. The flash memory controller of claim 9, wherein the delay chain comprises:
a plurality of delay circuits with different delay amount, configured to delay the input signal to generate a plurality of delayed signals, respectively; and
a multiplexer, configured to select one of the plurality of delayed signals to serve as the delayed input signal.

16. The flash memory controller of claim 9, wherein the glitch filter is configured to filter out a glitch whose glitch width is smaller than delay amount provided by the delay chain.
